(19) United States
(12) Patent Application Publication
(10) Pub. No.: US 2025/0291016 A1
(43) Pub. Date: Sep. 18, 2025

(54) Computer-Implemented Method for Operating a Magnetic Resonance Device for Acquiring Magnetic Resonance Data, Magnetic Resonance Device, Computer Program and Electronically Readable Storage Medium

(71) Applicant: Siemens Healthineers AG, Forchheim (DE)

(72) Inventors: Nicolas Groß-Weege, Nürnberg (DE); Guido Buonincontri, Vinci (IT)

(73) Assignee: Siemens Healthineers AG, Forchheim (DE)

(21) Appl. No.: 19/079,625

(22) Filed: Mar. 14, 2025

(30) Foreign Application Priority Data
Mar. 15, 2024 (EP) 24163813.9

(51) Int. Cl. G01R 33/561; G01R 33/54

(52) U.S. Cl. CPC G01R 33/5617; G01R 33/543

(57) ABSTRACT

A computer-implemented method for operating a magnetic resonance device for acquiring magnetic resonance data is provided. The method may include providing (e.g., determining) a three-dimensional, slab-selective turbo spin echo sequence having at least one echo train is used, each echo train comprising an excitation module with an excitation pulse preceding a readout module. The readout module may include multiple refocusing pulses and associated readout intervals. The excitation pulse may be at least partly implemented as a variable rate selective excitation pulse. The readout module may immediately succeed the excitation module.

### CROSS REFERENCE TO RELATED APPLICATIONS

This patent application claims priority to European Patent Application No. 24163813.9, filed Mar. 15, 2024, which is incorporated herein by reference in its entirety.

### BACKGROUND

### Field

The disclosure concerns a computer-implemented method for operating a magnetic resonance device for acquiring magnetic resonance data, wherein an, in particular three-dimensional, slab-selective turbo spin echo sequence having at least one echo train is used, each echo train comprising an excitation module with an excitation pulse preceding a readout module, which may comprise multiple refocusing pulses and associated readout intervals. The disclosure further concerns a magnetic resonance device, a computer program and an electronically readable storage medium.

### Related Art

Spin echo sequences are a workhorse in magnetic resonance imaging. To accelerate image acquisition, turbo spin echo (TSE, also known as fast spin echo (FSE) and originally proposed as Rapid Acquisition with Relaxation Enhancement (RARE)) sequences have been proposed, in which multiple echoes are acquired using the same excitation pulse, such that the excitation module and the following readout module may also be called an echo train, while the readout module itself may be understood as a refocusing train. In the readout module, each readout interval is preceded by a refocusing pulse (π pulse). Here, the flip angle of the refocusing pulse does not have to be 180°, since approaches for reducing the flip angle and hence specific absorption rate (SAR) are known. For example, in SPACE (Sampling Perfection with Application optimized Contrast using different flip angle Evolution) sequences, it has been proposed to significantly reduce SAR at comparable signal-to-noise ratio (SNR) by replacing a constant low flip angle refocusing train by a variable flip angle refocusing train designed to produce a constant echo amplitude. Starting the pulse train with higher amplitude refocusing pulses and slowly decreasing to approach a constant (“asymptotic”) value enables acquisition of images with SNR values close to those acquired with 180° refocusing pulses, for asymptotic flip angles as low as 60°.

Three-dimensional TSE sequences may be non-selective. Here, the excitation is not confined to a certain slice or slab. The excitation pulse and the refocusing pulses are both non-selective.

For slab-selective TSE sequences, at least the excitation pulse must be slab-selective. However, slab-selective excitation pulses have a longer duration. One of the reasons is that the excited slab needs to have a precise profile. As a consequence, the duration of the excitation pulse limits the echo spacing of the refocusing train. In SPACE, for example, the echo spacing is twice the time between the center of the excitation pulse and the center of the first refocusing pulse. Thus, increasing the duration of the excitation pulse would cause an increase in the echo spacing, which has detrimental effects on image quality.

For slab-selective SPACE, it has been proposed to use an additional refocusing module following the slab-selective excitation pulse in the excitation module. In this additional refocusing module, a non-selective 180° pulse generates a spin echo, which is used as the “new input” for the readout module (refocusing train). The method allows a reduction of the echo spacing to the same value as the non-selective SPACE. However, there are some disadvantages and challenges.

The flip angle of the 180° pulse must be very precise. Otherwise, only a part of the signal would be refocused and a significant part of the signal would be lost before the acquisition in the refocusing train. A precise flip angle over the complete field of view cannot be guaranteed, in particular for MRI systems with a main magnetic field (B0 field) strength of 3 Tesla or higher.
Since the first echo has a different echo spacing compared to the successive echoes, its higher-order echoes cannot contribute to the refocusing train without creating banding artifacts. To solve this problem, a crusher gradient pulse is output after the 180° pulse in the additional refocusing module to crush the contribution of the first echo. However, this can reduce the available signal for the successive refocusing train, in particular if there are main magnetic field (B0 field) and excitation magnetic field (B1 field) imperfections.
To achieve a flip angle of 180°, a high radio frequency amplitude is needed. To reduce the maximum radio frequency amplitude needed (in particular due to SAR limitations), the duration of the 180° pulse is increased compared to the other refocusing pulses of the refocusing train, resulting in a lower bandwidth and increased susceptibility to artifacts caused by B0 imperfections.
The addition of the additional refocusing module to each echo train increases the minimum echo time (TE) achievable. TE is a crucial parameter for the image quality of T1-weighted or proton density (PD)-weighted TSE imaging.
To achieve a precise slab selection, that is, an accurate slab profile, the radio frequency pulse of the excitation module has a high time-bandwidth product and hence a long duration. This can result in off-resonant tissues being shifted in the slab selection direction defined by the gradient pulse of the excitation module, which causes a geometrical inaccuracy.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 is a plot of a conventional sequence diagram.

FIG. 2 is a plot of a sequence diagram for illustrating a method according to an exemplary embodiment of the disclosure.

FIG. 3 is a plot of a sequence diagram for illustrating a method according to an exemplary embodiment of the disclosure.

FIG. 4 is a magnetic resonance device according to an exemplary embodiment of the disclosure.

FIG. 5 is a controller, according to an exemplary embodiment, of the magnetic resonance device of FIG. 4.

The exemplary embodiments of the present disclosure will be described with reference to the accompanying drawings. Elements, features and components that are identical, functionally identical and have the same effect are-insofar as is not stated otherwise-respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the disclosure is to provide a way to improve image quality of selective 3D-TSE imaging, in particular avoiding or at least mitigating the disadvantages encountered in an additional refocusing module approach.

This object is achieved by providing a computer-implemented method, a magnetic resonance device, a computer program and an electronically readable storage medium according to the disclosure.

In a method for operating a magnetic resonance device for acquiring magnetic resonance data, wherein an, in particular three-dimensional, slab-selective turbo spin echo sequence having at least one echo train is used, each echo train may comprise an excitation module with an excitation pulse preceding a readout module, which may comprise multiple refocusing pulses and associated readout intervals, according to the disclosure, the excitation pulse is at least partly implemented as a variable rate selective excitation pulse, wherein the readout module immediately succeeds the excitation module.

Here, a slab-selective excitation pulse is understood as comprising a gradient pulse and a radio frequency pulse (RF pulse). In a variable rate selective excitation pulse (VERSE pulse), both the gradient pulse and the radio frequency pulse are time-varying and may, for example, be determined in an optimization procedure, in particular minimizing duration. In other words, instead of a slab selective gradient with a constant gradient strength, VERSE pulses use slab selective gradients with time-varying gradient strength. VERSE pulses of minimized duration have been proposed, for example, by Brian A. Hargreaves et al. in “Variable-Rate Selective Excitation for Rapid MRI Sequences”, MRM 52 (2004), pages 590-597. It is also referred to US 2006/0061358 A1.

It is hence proposed to replace a conventional excitation pulse using constant gradient strength at least partly with a VERSE pulse having a reduced duration. The reduction in the excitation pulse duration is realized by the time modulation of the radio frequency pulse and of the gradient pulse (slab-selective gradient). In other words, the VERSE pulse part of the excitation pulse may have a duration which is at least five times shorter than a corresponding part having a constant gradient strength, in particular at least nine times shorter. VERSE allows, for example, to reduce the duration of the slab selective excitation pulse by nearly a factor of ten, which, in particular, allows the removal of the additional refocusing module mentioned above. In advantageous embodiments, the variable rate selective excitation pulse is determined by minimizing its duration. Such pulses are also called minimum-time VERSE pulses and have been introduced in the article by Hargreaves et al. and corresponding US patent application mentioned above for SSFP sequences.

Using VERSE pulses is advantageous in many ways, in particular in comparison to using an additional refocusing module. Generally, improved image quality is achieved for many MRI applications that use slab-selective 3D-TSE sequences. The signal-to-noise ratio (SNR) is improved. An additional refocusing module is no longer required, since the excitation pulse duration is considerably shorter, allowing an adequate choice of timing, in particular echo times.

In contrast to using an additional refocusing module, where the sensitivity to B0 and B1 imperfections is increased compared to the non-selective case, in the VERSE implementation, the sequence is less prone to B0 and B1 artifacts and behaves similarly to the non-selective case. A crusher gradient for “crushing” transverse magnetization before the first echo is no longer necessary, such that all available signal can be used in the readout module. Furthermore, VERSE allows to shorten the minimum echo time (TE), increasing the available signal. This is relevant especially for the image quality of proton density (PD) and T1-weighted 3D-TSE sequences. Finally, geometrical shifts in the selected slab are reduced, since the VERSE pulse is shorter. Hence, less geometrical imperfections occur.

In one or more embodiments, the excitation pulse may be completely implemented as a variable rate selective excitation pulse. Using only a VERSE pulse allows a very short excitation module, and, consequently, a reduced duration of each echo train, such that the imaging time can advantageously be reduced.

However, VERSE pulses come with the disadvantage that they are more prone to off-resonances caused, for example, by B0 inhomogeneities or chemical shifts. To improve on this, in an exemplary embodiment of the disclosure, the excitation pulse may comprise a first section implemented as a first half of a slab-selective excitation pulse having a constant gradient pulse and a second section implemented as a variable rate selective excitation pulse, wherein the second section has a shorter duration than the first section.

Hence, a “mixed” pulse can be used. The first section may comprise half a usual radio frequency pulse with a constant gradient pulse and the second section a VERSE pulse with a time-varying gradient. Since timing usually refers to the middle of the excitation pulse, it is sufficient to accelerate the second half of the excitation pulse. While it is generally noted that known techniques for determining minimum-time VERSE pulses, as for example proposed by Hargreaves et al., such approaches may also be applied to determining parts of excitation pulses, when the conventional part defines the starting conditions.

It is further noted that, if an additional refocusing module should still be used for some reason, using a “mixed” pulse as discussed above would also allow to reduce refocusing moment without increasing the echo spacing.

In examples, the three-dimensional slab-selective TSE sequence may be a slab-selective SPACE sequence. However, other concrete implementations of 3D-TSE sequences may also be used, while, generally, approaches using a reduced and/or variable flip angle are selected for one or more exemplary embodiments.

Regarding the readout module, it may comprise a CPMG (Car-Purcell-Meiboom-Gill) readout train. In this manner, in particular, SNR may additionally be improved.

A magnetic resonance device according to the disclosure may comprise a main magnet for generating a main magnetic field, acquisition equipment comprising a gradient coil assembly and a radio frequency coil assembly for outputting gradient pulses and radio frequency pulses, respectively, and a control device (controller). The controller may comprise an acquisition unit operative to acquire magnetic resonance data using the acquisition equipment and adapted to acquire magnetic resonance data using an, in particular three-dimensional, slab-selective turbo spin echo sequence having at least one echo train, each echo train comprising an excitation module with an excitation pulse preceding a readout module, which may comprise multiple refocusing pulses and associated readout intervals, wherein the excitation pulse is at least partly implemented as a variable rate selective excitation pulse and the readout module immediately succeeds the excitation module.

One or more features and remarks regarding the method according to the disclosure may also be applied to the magnetic resonance device according to the disclosure and vice versa. Hence, the same advantages can be achieved.

The controller may comprise at least one processor and at least one storage means. Functional units may be implemented using hardware and/or software. In addition to the acquisition unit, which may also control other acquisition processes, the controller may also comprise a reconstruction unit for reconstructing a magnetic resonance data set from acquired magnetic resonance data, in particular from magnetic resonance data acquired using the method described above.

A computer program according to the disclosure may be directly loaded into a storage means of a controller of a magnetic resonance device and may comprise program means, such that, when the computer program is executed on the controller, the controller is caused to perform the steps of a method according to the disclosure. The computer program may be stored on an electronically readable storage medium according to the disclosure, which hence may comprise control information stored thereon, which may comprise at least a computer program according to the disclosure, such that, when the electronically readable storage medium is used in a controller of a magnetic resonance device, the controller is configured to perform a method according to the disclosure. The electronically readable storage medium may be a non-transient medium, for example a CD-ROM.

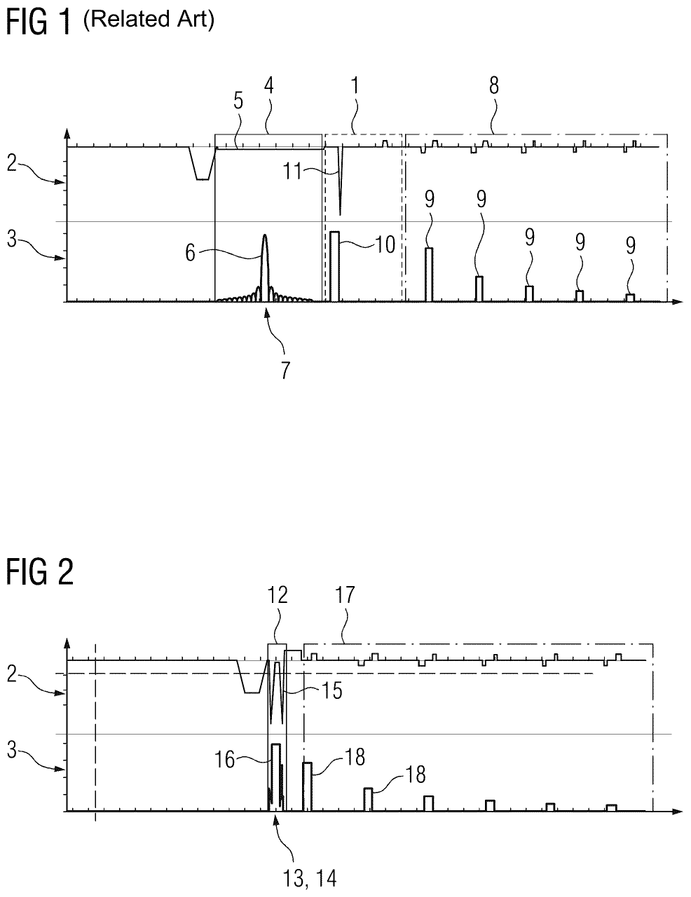

FIG. 1 illustrates a state-of-the-art approach using an additional refocusing module 1 for a slab-selective three-dimensional TSE sequence, in this case a SPACE sequence. For simplicity, in the sequence diagram, only the z gradient (upper graph 2) and the radio frequency channel (lower graph 3) are shown. The z gradient is used for slab selection.

As can be seen, the echo train illustrated in FIG. 1 may comprise an excitation module 4, wherein a low-amplitude gradient pulse 5 of constant strength and a radio frequency pulse 6 are output as an excitation pulse 7. The excitation pulse 7 has a high time-bandwidth product to achieve precise slice selection. It has a long duration, which would limit the echo spacing in the refocusing train (readout module 8). In the readout module 8, refocusing pulses 9 are succeeded by respective readout intervals (not shown).

To allow shorter echo spacings and shorter TEs, the refocusing module 1 is used, which may comprise an additional 180° refocusing pulse 10 and a crusher gradient pulse 11. The spin echo generated in the additional refocusing module serves as the input to the readout module 8. In this manner, echo spacings as on the non-selective case can be used. However, this solution has the disadvantages of requiring a very precise 180° refocusing pulse 10 and the crusher gradient 11 to mitigate effects of the different echo spacing of this first echo. Furthermore, when avoiding high radio frequency amplitudes to achieve the flip angle of 180°, the 180° refocusing pulse 10 has a longer duration, increasing the susceptibility for B0 inhomogeneities (imperfections). The minimum TE is increased when using the additional refocusing module 1. Finally, the long duration of the excitation pulse 7 leads to geometrical inaccuracies regarding different magnetic resonance frequencies in the slab, for example off-resonant tissues.

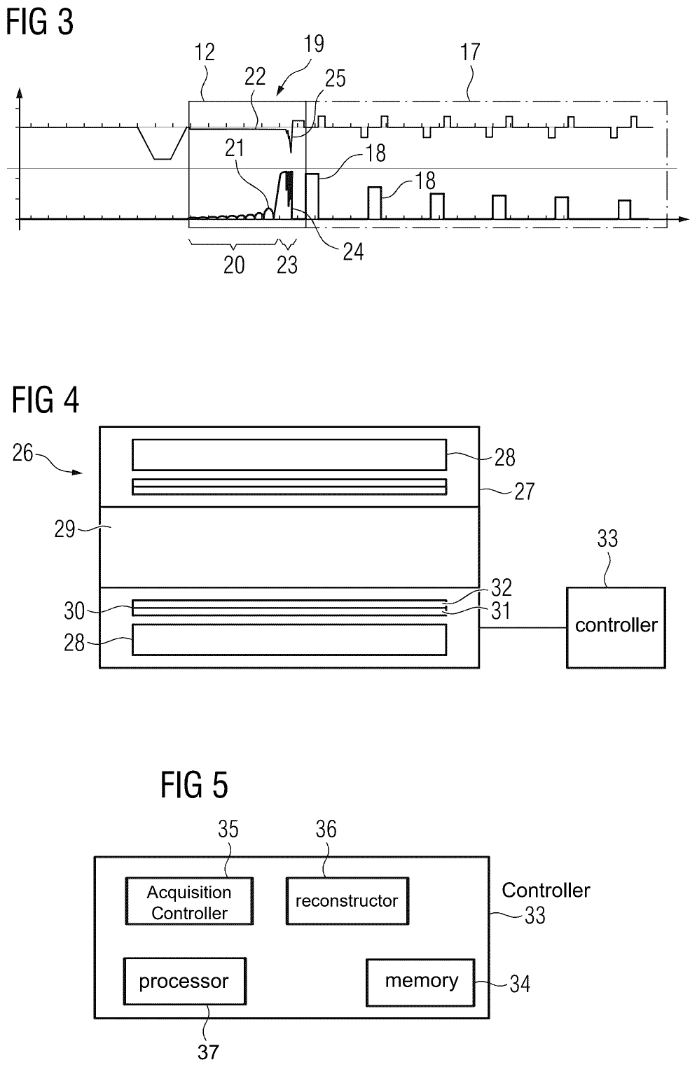

In embodiments of the current disclosure, it is proposed to replace the excitation pulse 7 at least partly by a VERSE pulse, shortening its duration and removing the need for the additional refocusing module 1. Concrete examples are shown in FIGS. 2 and 3. Again, for simplicity, in the respective sequence diagrams only the z gradient (upper graph 2) and the radio frequency channel (lower graph 3) are shown.

FIG. 2 illustrates a first embodiment of the disclosure. In the excitation module 12, only a VERSE pulse 13 is used as the excitation pulse 14. The VERSE pulse 13 may comprise a gradient pulse 15 having a time-varying gradient strength and radio frequency pulse 16. In this case, a minimum-time VERSE pulse 13 is used. The duration of the excitation pulse 14 is considerably shorter as the duration of the excitation pulse 7, for example reduced by a factor of nearly ten. The readout module 17 can be used immediately after the excitation module 12, since very short TEs are possible. Both embodiments shown here relate to a SPACE sequence using a CPMG train for readout, where the echo spacing of the refocusing train is twice the time between the center of the excitation pulse 14 and the center of the first refocusing pulse 18 of the refocusing module 17.

In the embodiment of FIG. 3, the fact that VERSE pulses are more prone to off-resonances caused, for example, by B0 inhomogeneities or chemical shifts is also considered. Hence, the excitation pulse 19 of the second embodiment may comprise a first section 20 implemented as a first half of a slab-selective excitation pulse having radio frequency pulse 21 and a constant gradient pulse 22 and a second section 23 implemented as a VERSE pulse comprising a radio frequency pulse 24 and a gradient pulse 25 of time-varying gradient strength. The second section 23 has a shorter duration than the first section 20, since the VERSE pulse has, again, been determined as a minimum time VERSE pulse. In this manner, the use of VERSE in minimized while maximizing the relevant decrease in duration, i.e. the duration from the center of the slab-selective excitation pulse having a constant gradient pulse 22, which defines the echo spacing, on is minimized.

FIG. 4 is a schematic drawing of a magnetic resonance device 26 according to the disclosure. The magnetic resonance device 26 may comprise a main magnet unit 27 having a superconducting main magnet 28, which defines a bore 29 into which a patient on a patient table (not shown) can be introduced for magnetic resonance imaging. Acquisition equipment 30 may comprise a gradient coil assembly 31 and a radio frequency coil assembly 32, which, in this embodiment, extend cylindrically around the bore 29. The main magnet unit 27 and the acquisition equipment 30 may collectively be referred to as a magnetic resonance scanner.

The operation of the magnetic resonance device 26 is controlled by a control device (controller) 33, which is configured to perform a method according to the disclosure. For example, the controller 33 may determine one or more of the sequences described with respect to FIG. 2 and/or FIG. 3, and generate an output signal (e.g., control signal). The output signal may be provided to the magnetic resonance device 26 to control the magnetic resonance device 26 to acquire magnetic resonance data. In an exemplary embodiment, the controller 33 includes processing circuitry that is configured to perform one or more functions and/or operations of the controller 33. Additionally, or alternatively, one or more components of the controller 33 may include processing circuitry that is configured to perform one or more respective functions and/or operations of the component(s).

FIG. 5 shows the functional structure of the controller 33. The controller 33 may comprise at least one processor 37 and memory (a storage means) 34, in which, for example, magnetic resonance data may be stored. An acquisition unit (acquisition controller) 35 may be configured to control the magnetic resonance device 26, in particular the acquisition equipment 30, to acquire magnetic resonance data, in particular according to the 3D-TSE sequences described with respect to FIG. 2 and FIG. 3. In a reconstruction unit (reconstructor) 36, magnetic resonance image data sets may be reconstructed from the magnetic resonance data.

Although the present disclosure has been described in detail with reference to the exemplary embodiment, the present disclosure is not limited by the disclosed examples from which the skilled person is able to derive other variations without departing from the scope of the disclosure.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium.

Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM).

The memory can be non-removable, removable, or a combination of both.

1. A computer-implemented method for operating a magnetic resonance (MR) device for acquiring MR data, the method comprising:
determining a three-dimensional, slab-selective turbo spin echo sequence having at least one echo train, each echo train comprising an excitation module with an excitation pulse preceding a readout module including multiple refocusing pulses and associated readout intervals, wherein: the excitation pulse is at least partly implemented as a variable rate selective excitation pulse, and the readout module immediately succeeds the excitation module; and
providing the sequence in electronic form as an output signal.

2. The method according to claim 1, wherein the variable rate selective excitation pulse is determined by minimizing its duration.

3. The method according to claim 1, wherein the excitation pulse is completely implemented as a variable rate selective excitation pulse.

4. The method according to claim 1, wherein the excitation pulse comprises a first section implemented as a first half of a slab-selective excitation pulse having a constant gradient pulse and a second section implemented as a variable rate selective excitation pulse, and wherein the second section has a shorter duration than the first section.

5. The method according to claim 2, wherein the excitation pulse is completely implemented as a variable rate selective excitation pulse.

6. The method according to claim 2, wherein the excitation pulse comprises a first section implemented as a first half of a slab-selective excitation pulse having a constant gradient pulse and a second section implemented as a variable rate selective excitation pulse, and wherein the second section has a shorter duration than the first section.

7. The method according to claim 1, wherein the readout module comprises a Car-Purcell-Meiboom-Gill (CPMG) readout train.

8. The method according to claim 1, wherein providing the sequence in electronic form as an output signal comprises controlling a MR scanner to acquire magnetic resonance data using the sequence.

9. The method according to claim 1, wherein providing the sequence in electronic form as an output signal comprises storing the sequence in a memory.

10. A non-transitory computer-readable storage medium with an executable program stored thereon, wherein, when executed, the program instructs a processor to perform the method of claim 1.

11. A magnetic resonance (MR) device, comprising:
a scanner; and
a controller configured to control the scanner to acquire magnetic resonance data using a three-dimensional, slab-selective turbo spin echo sequence having at least one echo train, each echo train comprising an excitation module with an excitation pulse preceding a readout module including multiple refocusing pulses and associated readout intervals, wherein the excitation pulse is at least partly implemented as a variable rate selective excitation pulse and the readout module immediately succeeds the excitation module.

12. The MR device according to claim 11, wherein the scanner comprises a main magnet configured to generate a main magnetic field, and acquisition equipment comprising a gradient coil assembly and a radio frequency coil assembly.

13. An apparatus comprising:
one or more processors; and
memory storing instructions that, when executed by the one or more processors, cause the apparatus to:
determine a three-dimensional, slab-selective turbo spin echo sequence having at least one echo train, each echo train comprising an excitation module with an excitation pulse preceding a readout module including multiple refocusing pulses and associated readout intervals, wherein: the excitation pulse is at least partly implemented as a variable rate selective excitation pulse, and the readout module immediately succeeds the excitation module; and
provide the sequence in electronic form as an output signal.

14. A magnetic resonance (MR) device comprising the apparatus of claim 13.
